(19) United States
(12) Patent Application Publication
(10) Pub. No.: US 2007/0048956 A1
(43) Pub. Date: Mar. 1, 2007

(54) Interrupted deposition process for selective deposition of Si-containing films

(75) Inventors: Anthony Dip, Cedar Creek, TX (US); Seungho Oh, Austin, TX (US); Allen John Leith, Austin, TX (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/213,871

(22) Filed: Aug. 30, 2005

(51) Int. Cl. H01L 21/331

(52) U.S. Cl. 438/312

(57) ABSTRACT

A method is provided for selectively forming a Si-containing film on a substrate in an interrupted deposition process. The method includes providing a substrate containing a growth surface and a non-growth surface, and selectively forming the Si-containing film on the growth surface by exposing the substrate to HX gas while simultaneously exposing the substrate to a pulse of chlorinated silane gas. The Si-containing film can be a Si film or a SiGe film that is selectively formed on a Si or SiGe growth surface but not on an oxide, nitride, or oxynitride non-growth surface.

### CROSS REFERENCE TO RELATED APPLICATIONS

The present invention is related to co-pending U.S. patent application Ser. No. xx/xxx,xxx, titled “SEQUENTIAL DEPOSITION PROCESS FOR FORMING Si-CONTAINING FILMS” filed on Aug. 18, 2005 and having Attorney Docket No. 276368US6YA, the entire content of which is hereby incorporated herein by reference.

### Field of the Invention

The present invention relates to semiconductor processing, and more particularly, to selectively forming Si-containing films on a substrate.

### BACKGROUND OF THE INVENTION

Silicon-containing films are used for a wide variety of applications in the semiconductor industry. Silicon-containing films include silicon films such as epitaxial silicon, polycrystalline silicon (poly-Si), and amorphous silicon, epitaxial silicon germanium (SiGe), polycrystalline silicon germanium (poly-SiGe), and amorphous silicon germanium. As circuit geometries shrink to ever smaller feature sizes, lower deposition temperatures for Si-containing films may be preferred, for example because of introduction of new temperature sensitive materials into semiconductor devices and reduction of thermal budgets of shallow implants in source and drain regions. It is also evident that non-selective (blanket) and selective deposition of Si-containing films will be needed for future devices.

Epitaxial deposition is a process where the crystal lattice of the bulk substrate is extended through deposition of a new film that may have a different doping level than the bulk. Accordingly, a surface of a single crystal Si (SiGe) substrate or film is required for depositing an epitaxial Si (SiGe) film thereon. Prior to depositing a Si-containing film on a substrate, for example epitaxial Si or epitaxial SiGe films, it may be required to remove a native oxide layer from the surface of the substrate in order to prepare a proper starting growth surface (i.e., a seed layer) to deposit a high quality epitaxial film. Moreover in epitaxial deposition, matching target epitaxial film thickness and resistivity parameters are important for the subsequent fabrication of properly functioning devices.

Typically, in selective epitaxial deposition, film nucleation and subsequent continuous film deposition is not desired on areas of the substrate containing dielectric materials such as nitrides, oxides, or oxynitrides. Furthermore, in part due to the use of new temperature sensitive materials in device manufacturing, selective epitaxial deposition may be required to be performed at increasingly lower substrate temperatures. However, selective epitaxial deposition and lowering of the substrate temperature are competing goals since selectivity is commonly reduced or lost at these lower substrate temperatures.

### SUMMARY OF THE INVENTION

Accordingly, one object of the present invention is to address any of the above described or other problems associated with selective deposition of Si-containing films.

Another object of the invention is to address problems associated selective deposition of Si-containing films as a result of requirements for reduced thermal budgets while maintaining deposition selectivity on growth vs non-growth surfaces of the substrate. According to embodiments of the invention, the Si-containing film can be a Si film or a SiGe film that is selectively formed on a Si or SiGe growth surface without forming the Si-containing film on an oxide, nitride, or oxynitride non-growth surface.

According to an embodiment of the invention, a method is provided for selectively forming a Si-containing film on a substrate in an interrupted deposition process. The method includes providing a substrate in a process chamber, the substrate containing a growth surface and a non-growth surface, and selectively forming the Si-containing film on the growth surface by exposing the substrate to HX gas while simultaneously exposing the substrate to a pulse cycle of chlorinated silane gas. The interrupted deposition process is carried out until a Si-containing film with a desired thickness is formed on the growth surface.

According to an embodiment of the invention, a method is provided for selectively forming a Si film on a substrate in an interrupted deposition process. The method includes providing a substrate in a process chamber, the substrate containing a Si growth surface and a non-growth surface, and selectively forming the Si film on the growth surface by continuously exposing the substrate to HCl gas while periodically exposing the substrate to a pulse of Si₂Cl₆ gas, wherein the substrate is maintained at a temperature between about 500° C. and about 700° C.

According to another embodiment of the invention, a method is provided for processing a substrate. The method includes providing the substrate in a process chamber, the substrate comprising a growth surface and a non-growth surface. Also included is selectively forming a Si film or a SiGe film on the growth surface by exposing the substrate to HX gas while simultaneously exposing the substrate to a pulse cycle of chlorinated silane gas.

### BRIEF DESCRIPTION OF THE DRAWINGS

In the accompanying drawings:

FIG. 1 shows a simplified block diagram of a batch processing system according to an embodiment of the invention;

FIG. 2 is a process diagram for selectively forming a Si-containing film on a substrate by an interrupted deposition process according to an embodiment of the invention;

FIGS. 3A-3C schematically show selective formation of a Si-containing film by an interrupted deposition process according to an embodiment of the invention; and

FIG. 4 is a gas flow diagram for selective formation of a Si-containing film by an interrupted deposition process according to an embodiment of the invention.

### DETAILED DESCRIPTION OF SEVERAL EMBODIMENTS OF THE INVENTION

Embodiments of the invention provide a method for low-temperature selective deposition of Si-containing films onto substrates. One embodiment of the method includes selectively forming a Si-containing film on a growth surface in an interrupted deposition process by continuously exposing the substrate to HX gas while periodically exposing the substrate to a chlorinated silane gas. The interrupted deposition process is separated into multiple deposition steps, where, in each deposition step, the substrate is exposed to a pulse of the chlorinated silane gas to deposit a Si-containing film on the substrate. Any Si-containing nuclei formed on a non-growth surface of the substrate during the pulse of the chlorinated silane gas are subsequently etched away by the HX gas before the next chlorinated silane gas pulse.

In the following description, in order to facilitate a thorough understanding of the invention and for purposes of explanation and not limitation, specific details are set forth, such as a particular geometry of the batch processing system and descriptions of various components. However, it should be understood that the invention may be practiced in other embodiments that depart from these specific details. In particular, embodiments of the invention provide a method for selectively forming Si-containing films on different materials on a substrate in an interrupted deposition process. The Si-containing films include Si films that are deposited from a chlorinated silane gas and SiGe films that are deposited from a chlorinated silane gas and a chlorinated germane gas or germane gas, respectively.

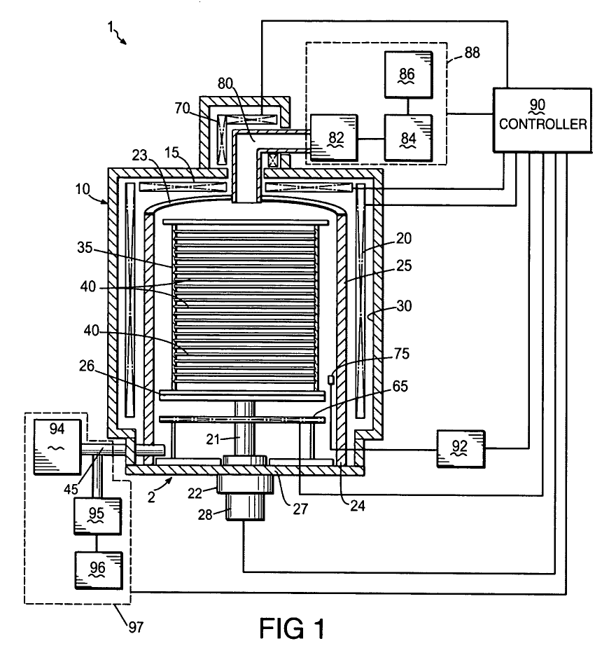

Referring now to the drawings, FIG. 1 shows a simplified block diagram of a batch processing system according to an embodiment of the invention. The batch processing system 1 contains a process chamber 10 and a process tube 25 that has an upper end 23 connected to an exhaust pipe 80, and a lower end 24 hermetically joined to a lid 27 of cylindrical manifold 2. The exhaust pipe 80 discharges gases from the process tube 25 to a vacuum pumping system 88 to maintain a pre-determined atmospheric or below atmospheric pressure in the processing system 1. A substrate holder 35 for holding a plurality of substrates (wafers) 40 in a tier-like manner (in respective horizontal planes at vertical intervals) is placed in the process tube 25. The substrate holder 35 resides on a turntable 26 that is mounted on a rotating shaft 21 penetrating the lid 27 and driven by a motor 28. The turntable 26 can be rotated during processing to improve overall film uniformity or, alternately, the turntable can be stationary during processing. The lid 27 is mounted on an elevator 22 for transferring the substrate holder 35 in and out of the process tube 25. When the lid 27 is positioned at its uppermost position, the lid 27 is adapted to close the open end of the manifold 2.

A gas delivery system 97 is configured for introducing gases into the process chamber 10. A plurality of gas supply lines can be arranged around the manifold 2 to supply a plurality of gases into the process tube 25 through the gas supply lines. In FIG. 1, only one gas supply line 45 among the plurality of gas supply lines is shown. The gas supply line 45 shown, is connected to a first gas source 94. In general, the first gas source 94 can supply gases for processing the substrates 40, including gases for forming films (e.g., chlorinated silane gases, germanium-containing gases, and HX gases) onto the substrates 40.

In addition, or in the alternate, one or more of the gases can be supplied from the (remote) plasma source 95 that is operatively coupled to a second gas source 96 and to the process chamber 10 by the gas supply line 45. The plasma-excited gas is introduced into the process tube 25 by the gas supply line 45. The plasma source 95 can, for example, be a microwave plasma source, a radio frequency (RF) plasma source, or a plasma source powered by light radiation. In the case of a microwave plasma source, the microwave power can be between about 500 Watts (W) and about 5,000 W. The microwave frequency can, for example, be 2.45 GHz or 8.3 GHz. In one example, the remote plasma source can be a Downstream Plasma Source Type AX7610, manufactured by MKS Instruments, Wilmington, Mass., USA.

A cylindrical heat reflector 30 is disposed so as to cover the reaction tube 25. The heat reflector 30 has a mirror-finished inner surface to suppress dissipation of radiation heat radiated by main heater 20, bottom heater 65, top heater 15, and exhaust pipe heater 70. A helical cooling water passage (not shown) can be formed in the wall of the process chamber 10 as a cooling medium passage. The heaters 20, 65, and 15 can, for example, maintain the temperature of the substrates 40 between about 20° C. and about 900° C.

The vacuum pumping system 88 comprises a vacuum pump 86, a trap 84, and automatic pressure controller (APC) 82. The vacuum pump 86 can, for example, include a dry vacuum pump capable of a pumping speed up to 20,000 liters per second (and greater). During processing, gases can be introduced into the process chamber 10 via the gas supply line 45 of the gas delivery system 97 and the process pressure can be adjusted by the APC 82. The trap 84 can collect unreacted precursor material and by-products from the process chamber 10.

The process monitoring system 92 comprises a sensor 75 capable of real-time process monitoring and can, for example, include a mass spectrometer (MS), a FTIR spectrometer, or a particle counter. A controller 90 includes a microprocessor, a memory, and a digital I/O port capable of generating control voltages sufficient to communicate and activate inputs to the processing system 1 as well as monitor outputs from the processing system 1. Moreover, the controller 90 is coupled to and can exchange information with gas delivery system 97, motor 28, process monitoring system 92, heaters 20, 15, 65, and 70, and vacuum pumping system 88. The controller 90 may be implemented as a DELL PRECISION WORKSTATION 610™. The controller 90 may also be implemented as a general purpose computer, processor, digital signal processor, etc., which causes a substrate processing apparatus to perform a portion or all of the processing steps of the invention in response to the controller 90 executing one or more sequences of one or more instructions contained in a computer readable medium. The computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

The controller 90 may be locally located relative to the processing system 1, or it may be remotely located relative to the processing system 1 via an internet or intranet. Thus, the controller 90 can exchange data with the processing system 1 using at least one of a direct connection, an intranet, and the internet. The controller 90 may be coupled to an intranet at a customer site (i.e., a device maker, etc.), or coupled to an intranet at a vendor site (i.e., an equipment manufacturer). Furthermore, another computer (i.e., controller, server, etc.) can access controller 90 to exchange data via at least one of a direct connection, an intranet, and the internet.

It is to be understood that the batch processing system 1 depicted in FIG. 1 is shown for exemplary purposes only, as many variations of the specific hardware can be used to practice the present invention, and these variations will be readily apparent to one having ordinary skill in the art. The processing system 1 in FIG. 1 can, for example, process substrates of any size, such as 200 mm substrates, 300 mm substrates, or even larger substrates. Furthermore, the processing system 1 can simultaneously process up to about 200 substrates, or more. Alternately, the processing system 1 can simultaneously process up to about 25 substrates.

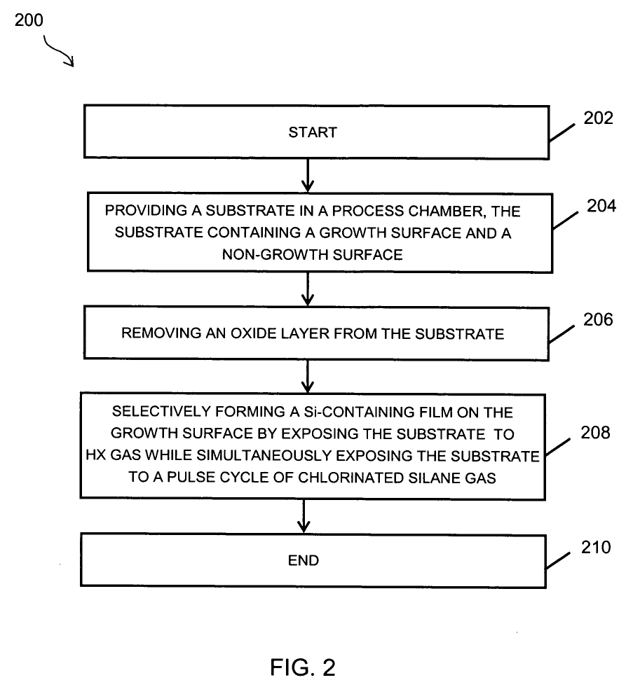

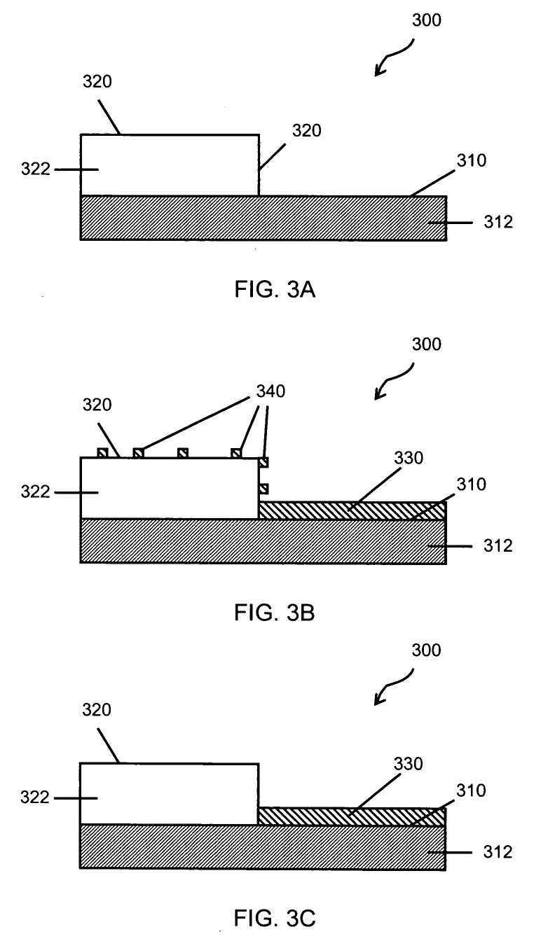

Reference will now be made to FIGS. 2-4. FIG. 2 is a process diagram for selectively forming a Si-containing film on a substrate by an interrupted deposition process according to an embodiment of the invention. FIGS. 3A-3C schematically show selective deposition of a Si-containing film on a substrate according to an embodiment of the invention. In FIG. 2, the process 200 starts at 202. In step 204, a substrate 310 is provided in a process chamber. The process chamber can, for example, be the process chamber 10 of the batch processing system 1 depicted in FIG. 1. Alternatively, the processing system can be a single wafer processing system. The substrate 300 contains a substrate material 312 having a growth surface 310 and a material 312 having non-growth surface 320. The substrate material 312 and the growth surface 310 can, for example, be Si or SiGe. The material 322 and non-growth surface 320 can, for example, be an oxide surface, a nitride surface, or an oxynitride surface including, for example, SiN, SiCN, SiON, SiCO, a glass surface, a LCD surface, or a compound semiconductor surface. In another example, the material 322 can contain a photoresist material. In one example, embodiments of the invention can be utilized to selectively form a Si-containing film on a patterned substrate containing vias or trenches or combinations thereof.

The growth surface 310 depicted in FIG. 3A may contain an oxide layer formed thereon (not shown). If present, the oxide layer may be removed from the growth surface 310 in step 206. Removal of the oxide layer, and any other surface contamination, creates a clean growth surface 310 that can enable subsequent deposition of an epitaxial Si-containing film such as Si or SiGe film on the growth surface 310 where the crystal lattice of the bulk substrate is extended through growth of the new film. The oxide layer may be a native oxide layer that forms easily on Si-containing substrates when exposed to air, even at room temperature. In addition to inhibiting proper film seeding and epitaxial film growth, the presence of an oxide layer can also reduce deposition selectivity on different materials. Alternately, the step 206 may be omitted from the process 200 if, for example, the growth surface 310 is clean when provided in the process chamber or if deposition of an epitaxial film is not desired. Exemplary methods and systems for removing an oxide layer from a substrate are described in co-pending U.S. patent application Ser. No. 11/094,462, titled “A METHOD AND SYSTEM FOR REMOVING AN OXIDE FROM A SURFACE”, and 11/xxx,xxx titled “LOW TEMPERATURE OXIDE REMOVAL USING FLUORINE” filed on Aug. 18, 2005 and having Attorney Docket No. 273849US, and the entire contents of both of these applications is hereby incorporated herein by reference.

In step 208, a Si-containing film is selectively formed on the growth surface 310 by exposing the substrate 300 to HX gas while simultaneously exposing the substrate 300 to a pulse of chlorinated silane gas. In step 210, the process ends. As used herein, “exposing the substrate to HX gas while simultaneously exposing the substrate to a pulse cycle of chlorinated gas means that the substrate is exposed to HX during at least a portion of the on-time for the chlorinated silane gas and also exposed to HX during at least a portion of the off-time for the chlorinated gas. In a preferred embodiment, the substrate 300 is continuously exposed to HX gas while being periodically exposed to pulses of chlorinated silane gas. As used herein, “continuous flow” means that the HX gas is flowed without interruption during a period where a flow of the chlorinated silane gas is interrupted at least once.

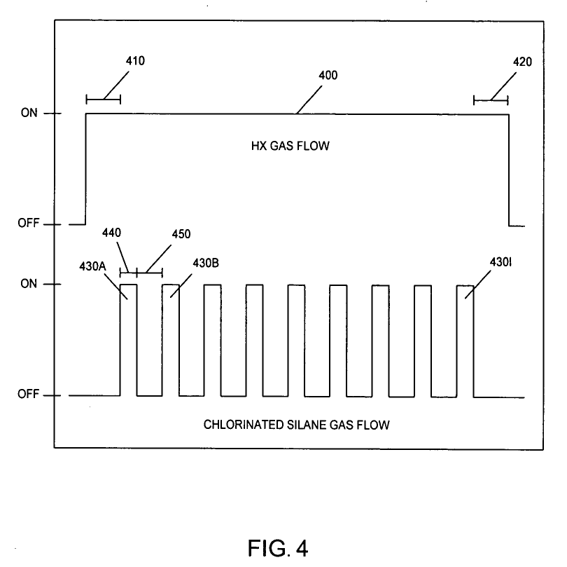

FIG. 4 is a gas flow diagram for selective formation of a Si-containing film by an interrupted deposition process according to an embodiment of the invention. A continuous flow 400 of HX gas is exposed to the substrate 300 while periodically exposing the substrate 300 to pulses 430A-430I of chlorinated silane gas. As shown in FIG. 4, the periodic exposure of the chlorinated silane gas includes separate pulses 430A-430I, each having a pulse length (deposition period or “on-time”) 440. The exemplary interrupted gas flow depicted in FIG. 4 includes 9 pulses of the chlorinated silane gas but this is not required for the invention as any number of pulses may be utilized. According to one embodiment of the invention, the number of chlorinated silane gas pulses may be between 1 and about 1000. According to another embodiment of the invention, the number of pulses may be between 10 and about 200. Each pulse is separated by an etch period 450 (“off-time” for the chlorinated silane gas) where only HX gas exposed to the substrate 300. According to an embodiment of the invention, each of the pulses 430A-430I may have the same length (as shown in FIG. 4), or alternately, the pulse lengths may vary. Analogously, each etch period 450 may have the same length (as shown in FIG. 4), or alternately, each etch period may have different length. As seen in FIG. 4, a pulse cycle of the chlorinated silane gas is equal to an on-time plus an off-time for the chlorinated silane gases.

In addition, FIG. 4 shows a HX pre-deposition purge time period 410 and a HX post-deposition purge time period 420, but these purge time periods are not required for the invention and may be omitted if desired.

While FIG. 4 shows continuous flow of HX gas during pulsing of the chlorinated silane gas, simultaneous exposure to a pulse cycle is not limited to continuous flow as noted above. For example, the HX gas itself could be pulsed such that an on-time for the HX gas runs through a portion of the on-time and a portion of the off-time for the chlorinated silane gas.

FIG. 3B shows formation of a Si-containing film following exposure of a pulse 430A of chlorinated silane gas to the substrate 300 while continuously exposing the substrate 300 to HX gas. During the time period 440 of the pulse 430A, a Si-containing film 330 is continuously deposited on the growth surface 310 and Si-containing nuclei 340 are formed on the non-growth surface 320. For a stable continuous Si-containing film 330 to form, Si-containing nuclei on the growth surface 310 must reach a critical size. If the Si-containing film 330 contains nuclei that are smaller than a critical size, they are unstable and are etched away during the etch period 450 shown in FIG. 4. Analogously, the pulse 430A of the chlorinated silane gas must be kept short enough to prevent the Si-containing nuclei 340 on the non-growth surface 320 to reach a critical stable size, thereby enabling unstable nuclei to be etched away from the non-growth surface 320 during the etch period 450. The deposition rate of the Si-containing film 330 on the growth surface 310 is typically much greater than on the non-growth surface 320 due to in part to shorter incubation time on the growth surface 310, thereby enabling deposition of the continuous Si-containing film 330 with stable nuclei that are not significantly etched away during the etch period 450.

In addition to etching away the unstable nuclei from the non-growth surface 320, the continuous HX gas flow 400 can reduce the deposition rate of the Si-containing film 330, thereby providing greater accuracy in controlling the overall deposition time. Further, the HX gas flow can assist in reducing the chlorine content of the Si-containing film 330. The U.S. Patent Application entitled “SEQUENTIAL DEPOSITION PROCESS FOR FORMING Si-CONTAINING FILMS” having Attorney Docket No. 276368US6YA, which is incorporated herein, describes a process for using dry etching of a chlorinated Si-containing film to reduce a chlorine content of the film. The continuous flow of HX gas may also provide this benefit.

FIG. 3C depicts selective formation of a Si-containing film after a pulse 430A of the chlorinated silane gas for a time period 440 and an etch time period 450. The exposure of the substrate to the HX gas during the etch period 450 removes the Si-containing nuclei 340 from the non-growth surface 320. Following removal of the Si-containing nuclei 340, the pulsing and etching may be repeated until a Si-containing film 330 with a desired thickness is selectively formed on the growth surface 310.

The length 440 of the chlorinated silane gas pulse 430A and the length of the etch period 450 are selected to provide selective deposition of the Si-containing film 330 on the growth surface 310. The lengths 440 of the chlorinated silane gas pulse 430A can be selected to avoid formation of nuclei 340 that are greater than a critical size and the length of the etch periods can be selected to sufficiently etch away the nuclei 340. The pulse length 440 and the length of the etch period 450 may, for example, be varied independently or together to achieve the desired selective deposition of the Si-containing film 330. According to an embodiment of the invention, the pulse length 440 can be between about 0.5 min and about 10 min. Alternately, the pulse length 440 can be between about 1 min and about 5 min. According to an embodiment of the invention, the length of the etch period 450 can be between about 1 min and about 20 min. Alternately, the length of the etch period can be between about 2 min and about 15 min.

According to an embodiment of the invention, the chlorinated silane gas can contain SiCl₄, SiHCl₃, SiH₂Cl₂, SiH₃Cl, or Si₂Cl₆, or a combination of two or more thereof. The chlorinated silane gas can further contain an inert gas, Cl₂, H₂, or H, or a combination of two or more thereof. The inert gas can, for example, contain N₂ or a noble gas (e.g., Ar). The flow rate of the chlorinated silane gas can between about 10 sccm and about 500 sccm. Alternately, the flow rate of the chlorinated silane gas may be selected to yield a growth rate of the Si-containing film that is between about 0.5 Angstrom/min and about 10 Angstrom/min. Alternately, the flow rate can be selected to yield a growth rate between about 1 Angstrom/min and about 2 Angstrom/min.

According to an embodiment of the invention, the HX gas can contain HF, HCl, HBr, or Hl, or a combination of two or more thereof. The HX gas can further contain an inert gas such as N₂ or a noble gas (e.g., Ar). According to an embodiment of the invention, a flow rate of the HX gas can be between about 10 sccm and about 500 sccm.

During the selective deposition process, the substrate temperature can be selected in consideration of the overall thermal budget, the desired deposition rate, or the desired crystal structure of the deposited Si-containing film 330 (e.g., single crystal, polycrystalline, or amorphous). Other adjustable process parameters include process chamber pressure, choice of the chlorinated silane gas and the HX gas, and the length 440 of the pulse 430A and the length of the etching period 450. According to an embodiment of the invention, the process chamber pressure can be between about 0.1 Torr and about 100 Torr. Alternately, the process chamber pressure can be between about 0.5 Torr and about 20 Torr. According to an embodiment of the invention, the substrate can be maintained at a substrate temperature between about 500° C. and about 700° C. Alternately, the substrate can be maintained at a substrate temperature between about 550° C. and about 650° C.

According to one embodiment of the invention, the process chamber pressure may be different during the time period 440 of the pulse 430A and during the etch period 450. In one example, the process chamber pressure may be higher during the etch period 450 than the time period 440 to increase the etch rate of the Si-containing nuclei on the non-growth surface and reduce the length of the etch period 450.

According to one embodiment of the invention, a Si film may be selectively deposited onto a substrate using Si₂Cl₆ gas and HCl gas. In one example, a Si film was selectively deposited on a substrate containing a Si growth surface and a SiN non-growth surface. The process conditions included a substrate temperature of 650° C., a process chamber pressure of 1 Torr, a continuous HCl gas flow of 60 sccm, 30 pulses of Si₂Cl₆ gas, where each pulse was 2.5 min long and separated from the next pulse by 10 min of HCl gas flow. The Si₂Cl₆ gas flow rate was 40 sccm, resulting in a Si deposition rate of 1.6 Angstrom/min.

In another example, a Si film was selectively deposited on a substrate containing a Si growth surface and a SiN non-growth surface. The process conditions included a substrate temperature of 600° C., a process chamber pressure of 2.2 Torr, a continuous HCl gas flow of 180 sccm, 45 pulses of Si₂Cl₆ gas, each pulse was 1 min long and separated from the next pulse by 5 min of HCl gas flow. The Si₂Cl₆ gas flow rate was 40 sccm, resulting in a Si deposition rate of 1.5 Angstrom/min.

According to an embodiment of the invention, the selectively deposited Si-containing film may be a SiGe film. A SiGe film may be deposited by adding a germanium-containing gas to the chlorinated silane gas. The germanium-containing gas can, for example, contain GeCl₄, GeHCl₃, GeH₂Cl₂, GeH₃Cl, Ge₂Cl₆, or GeH₄, or a combination of two or more thereof.

The Si-containing films may be doped by adding a dopant gas to the chlorinated silane gas, the germanium-containing gas, or the HX gas. The dopant gas can, for example, contain PH₃, AsH₃, B₂Cl₆, or BCl₃, to dope the Si-containing film with P, As, or B, respectively. It is contemplated that a sufficiently long exposure of a dopant gas will result in a highly doped Si-containing film that can, for example, be used for raised source/drain applications. In general, doping concentration less than saturation can be achieved by controlling the dopant gas concentration and exposure time to a dopant gas.

The selective deposition of the Si-containing film 330 depicted in FIG. 3C allows for subsequent removal of the material 322 from the substrate using methods known to those skilled in the art, to form a raised epitaxial Si-containing film on the substrate. The use of selective deposition of epitaxial Si-containing films can be used for manufacturing silicon-on-insulator (SOI) devices with a raised source and drain regions. During SOI device fabrication, processing may consume an entire Si film in source and drain regions, thereby requiring extra Si in these regions that can be provided by selective epitaxial growth (SEG) of Si films. Selective epitaxial deposition of Si-containing films can reduce the number of photolithography and etch steps that are needed, which can reduce the overall cost and complexity involved in manufacturing a device.

Although only certain embodiments of this invention have been described in detail above, those skilled in the art will readily appreciate that many modifications are possible in the exemplary embodiment without materially departing from the novel teachings and advantages of this invention. Accordingly, all such modifications are intended to be included within the scope of this invention.

What is claimed is:

1. A method for processing a substrate, comprising:
providing the substrate in a process chamber, the substrate comprising a growth surface and a non-growth surface; and
selectively forming a Si-containing film on the growth surface by exposing the substrate to HX gas while simultaneously exposing the substrate to a pulse cycle of chlorinated silane gas.

2. The method according to claim 1, wherein the growth surface comprises Si or SiGe and the non-growth surface comprises an oxide layer, a nitride layer, or an oxynitride layer.

3. The method according to claim 1, wherein the Si-containing film comprises poly-Si, amorphous Si, epitaxial Si, poly-SiGe, amorphous SiGe, or epitaxial SiGe.

4. The method according to claim 1, wherein the Si-containing film comprises Si and the chlorinated silane gas comprises SiCl₄, SiHCl₃, SiH₂Cl₂, SiH₃Cl, or Si₂Cl₆, or a combination of two or more thereof.

5. The method according to claim 1, wherein the chlorinated silane gas further comprises an inert gas, Cl₂, H₂, or H, or a combination of two or more thereof.

6. The method according to claim 1, wherein the HX gas comprises HF, HCl, HBr, or Hl, or a combination of two or more thereof.

7. The method according to claim 1, wherein said selectively forming comprises continuously exposing the substrate to HX gas while periodically exposing the substrate to a plurality of pulses of chlorinated silane gas.

8. The method according to claim 7, wherein a number of the clorinated silane gas pulses is between 1 and about 1000.

9. The method according to claim 7, wherein a number of the chlorinated silane gas pulses is between about 10 and about 200.

10. The method according to claim 7, wherein a flow rate of the HX gas is between about 10 sccm and about 500 sccm.

11. The method according to claim 7, wherein a growth rate of the Si-containing film is between about 0.5 Angstrom/min and about 10 Angstrom/min.

12. The method according to claim 7, wherein a growth rate of the Si-containing film is between about 1 Angstrom/min and about 2 Angstrom/min.

13. The method according to claim 7, wherein a pressure of the process chamber is between about 0.1 Torr and about 100 Torr.

14. The method according to claim 7, wherein a pressure of the process chamber is between about 0.5 Torr and about 20 Torr.

15. The method according to claim 1, further comprising:
removing an oxide layer from the substrate prior to the selectively forming, the removing comprising exposing the substrate to a cleaning gas comprising F₂, Cl₂, H₂, HCl, HF, or H, or a combination of two or more thereof.

16. The method according to claim 1, further comprising exposing the substrate to pre-deposition HX gas purge, post-deposition HX gas purge, or both.

17. The method according to claim 1, wherein the Si-containing film comprises SiGe and the chlorinated silane gas further comprises a germanium-containing gas.

18. The method according to claim 17, wherein the chlorinated silane gas comprises SiCl₄, SiHCl₃, SiH₂Cl₂, SiH₃Cl, or Si₂Cl₆, or a combination of two or more thereof, and the germanium-containing gas comprises GeCl₄, GeHCl₃, GeH₂Cl₂, GeH₃Cl, Ge₂Cl₆, or GeH₄, or a combination of two or more thereof.

19. The method according to claim 7, wherein the substrate is maintained at a temperature between about 500° C. and about 700° C.

20. The method according to claim 7, wherein the substrate is maintained at a temperature between about 550° C. and about 650° C.

21. The method according to claim 1, further comprising exposing the substrate to a dopant gas comprising PH₃, AsH₃, B₂Cl₆, or BCl₃, or a combination of two or more thereof.

22. The method of claim 7, wherein an on-time of each pulse of chlorinated silane gas is selected to substantially avoid formation of nuclei on the non-growth surface that are greater than a critical size.

23. The method of claim 1, wherein an off-time between said pulses of silane gas is selected to allow the HX exposure to substantially etch away nuclei from the non-growth surface.

24. The method of claim 23, wherein a pressure of the process chamber is higher during said off-time than an on-time of said pulses.

25. A method for processing a substrate, comprising:
providing the substrate in a process chamber, the substrate comprising an epitaxial Si growth surface and a non-growth surface; and
selectively forming an epitaxial Si film on the Si growth surface by continuously exposing the substrate to HCl gas while periodically exposing the substrate to pulses of Si₂Cl₆ gas, wherein the substrate is maintained at a temperature between about 500° C. and about 700° C.

26. A method for processing a substrate, comprising:
providing the substrate in a process chamber, the substrate comprising a growth surface and a non-growth surface; and
selectively forming a Si film or a SiGe film on the growth surface by exposing the substrate to HX gas while simultaneously exposing the substrate to a pulse cycle of chlorinated silane gas.
